(19) United States
(12) Patent Application Publication
(10) Pub. No.: US 2014/0061825 A1
(43) Pub. Date: Mar. 6, 2014

(54) MICRO ELECTRO MECHANICAL SYSTEM(MEMS) ACOUSTIC SENSOR AND FABRICATION METHOD THEREOF

(71) Applicant: Electronics and Telecommunications Research Institute, (US)

(72) Inventors: Jae Woo LEE, Daejeon (KR); Chang Han JE, Daejeon (KR); Woo Seok YANG, Daejeon (KR); Jong Dae KIM, Daejeon (KR)

(73) Assignee: Electronics and Telecommunications Research Institute, Daejeon (KR)

(21) Appl. No.: 13/873,195

(22) Filed: Apr. 29, 2013

(30) Foreign Application Priority Data
Aug. 29, 2012 (KR) 10-2012-0094819

(51) Int. Cl. B81B 3/00; B81C 1/00

(52) U.S. Cl. CPC B81B 3/0018; B81C 1/00158
USPC 257/416; 438/53

(57) ABSTRACT

Provided are a micro electro mechanical system (MEMS) acoustic sensor for removing a nonlinear component that occurs due to a vertical motion of a lower electrode when external sound pressure is received by fixing the lower electrode to a substrate using a fixing pin, and a fabrication method thereof. The MEMS acoustic sensor removes an undesired vertical motion of a fixed electrode when sound pressure is received by forming a fixing groove on a portion of the substrate and then forming a fixing pin on the fixing groove, and fixing the fixed electrode to the substrate using the fixing pin, and thereby improves a frequency response characteristic and also improves a yield of a process by inhibiting thermal deformation of the fixed electrode that may occur during the process.

### CROSS-REFERENCE TO RELATED APPLICATIONS

This application is based on and claims priority from Korean Patent Application No. 10-2012-0094819, filed on Aug. 29, 2012, with the Korean Intellectual Property Office, the disclosure of which is incorporated herein in its entirety by reference.

### TECHNICAL FIELD

The present disclosure relates to a micro electro mechanical system (MEMS) acoustic sensor and a fabrication method thereof, and more particularly, to a MEMS acoustic sensor for removing a nonlinear component that occurs due to a vertical motion of a lower electrode when external sound pressure is received by fixing the lower electrode to a substrate using a fixing pin, and a fabrication method thereof.

### BACKGROUND

Research on a micro electro mechanical system (MEMS) microphone is divided into a piezoelectric type (piezo-type) and a condenser type.

The piezoelectric type uses a piezo effect of when a potential difference occurs at both ends of a piezoelectric material when physical pressure is applied to the piezoelectric material. The piezoelectric type converts a sound signal to an electrical signal based on pressure of the sound signal, but has many limitations in the scope of applications due to a low band and an irregular sound band frequency characteristic.

The condenser type is based on a principle of a condenser that enables two electrodes to face other. Here, one pole of a microphone is fixed and the other pole functions as a diaphragm. When the diaphragm vibrates in reaction to a sound source, capacitance between the fixed pole and the diaphragm varies and accumulated charges vary whereby current flows. The condenser type has advantages such as stability and an excellent frequency characteristic.

Due to an excellent frequency response characteristic of a voice band, most MEMS microphones have used the condenser type.

### SUMMARY

The present disclosure has been made in an effort to provide an acoustic sensor that may improve a sound pressure characteristic by inhibiting a nonlinear operation characteristic in a further stable structure by inserting a fixing pin into and below a lower electrode used as a fixed electrode, and may improve a process yield by inhibiting thermal deformation of the fixed electrode that may occur during a fabrication process, and a fabrication method thereof.

An exemplary embodiment of the present disclosure provides a method of fabricating a micro electro mechanical system (MEMS) acoustic sensor, the method including forming a fixing groove by etching a portion of a substrate; forming a fixing pin by forming an insulating film on the substrate on which the fixing groove is formed, and by flattening the formed insulating film; forming a fixed electrode on the substrate on which the fixing pin is formed; forming a sacrificial layer on the fixed electrode; forming a diaphragm to face the fixed electrode based on the sacrificial layer, and a diaphragm supporter to support the diaphragm on the side of the diaphragm; forming an acoustic chamber by etching a portion of the substrate; and etching and thereby removing the sacrificial layer.

The forming of the fixed electrode includes sequentially forming, on the substrate, a substrate insulating film, a lower electrode, and a lower electrode insulating film; and forming a sound pressure input hole that penetrates from the lower electrode insulating film to the substrate insulating film.

The removing of the sacrificial layer selectively etches and thereby removes the sacrificial layer by injecting etching gas through the sound pressure input hole from the acoustic chamber.

The sacrificial layer is formed using a material having etching selectivity different from the lower electrode insulating film and the substrate insulating film.

The forming of the fixing pin flattens the insulating film so that the substrate surface on which the fixing groove is not formed is exposed.

Another exemplary embodiment of the present disclosure provides a MEMS acoustic sensor, including a substrate on which a fixing pin is formed and in which inside of the fixing pin is hollow; a fixed electrode fixed on the substrate using the fixing pin; and a diaphragm formed to be separate from above the fixed electrode by a predetermined interval, and configured to vibrate in reaction to external sound pressure. An acoustic chamber is formed in a space covered by the substrate and the fixed electrode.

The fixed electrode includes a lower electrode, a lower electrode insulating film, and a substrate insulating film.

At least one sound pressure input hole for receiving sound pressure through the acoustic chamber is formed in the fixed electrode.

The MEMS acoustic sensor further includes a diaphragm supporter formed on the lower electrode insulating film to connect the diaphragm to the substrate.

The diaphragm supporter is integrally formed with the diaphragm.

According to the exemplary embodiments of the present disclosure, a lower electrode may be tightly fixed within a substrate by inserting a fixing pin into and below the fixed electrode and thus, it is possible to improve a frequency response characteristic by removing an undesired vertical motion of the fixed electrode when sound pressure is received.

According to the exemplary embodiments of the present disclosure, it is possible to improve a yield of a process by inhibiting, using a fixing pin, thermal deformation of a fixed electrode that may occur during the process.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a top view of a package integrated acoustic sensor according to an exemplary embodiment of the present disclosure.

FIG. 2 is a cross-sectional view taken along line I-I′ of FIG. 1.

FIG. 3 is a perspective view taken along line I-I′ of FIG. 1.

FIGS. 4A, 5A, 6A, 7A, 8A, 9A, and 10A are top views and FIGS. 4B, 5B, 6B, 7B, 8B, 9B, and 10B are cross-sectional views taken along lines I-I′ of FIGS. 4A, 5A, 6A, 7A, 8A, 9A, and 10A to describe a method of fabricating an acoustic sensor according to an exemplary embodiment of the present disclosure.

FIG. 5C is a perspective view of FIG. 5A, and FIG. 10C is a top view observed from the bottom surface of a substrate of FIG. 10A.

### DETAILED DESCRIPTION

In the following detailed description, reference is made to the accompanying drawing, which form a part hereof The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments of the present disclosure will be described in detail with reference to the accompanying drawings. A configuration of the present disclosure and an operation effect according thereto will be understood clearly from the following detailed description. Prior to describing the detailed description of the present disclosure, it should be noted that like reference numerals refer to like constituent elements even though they are illustrated in different drawings, and that when it is determined detailed description related to a known function or configuration they may render the purpose of the present disclosure unnecessarily ambiguous, the detailed description will be omitted here.

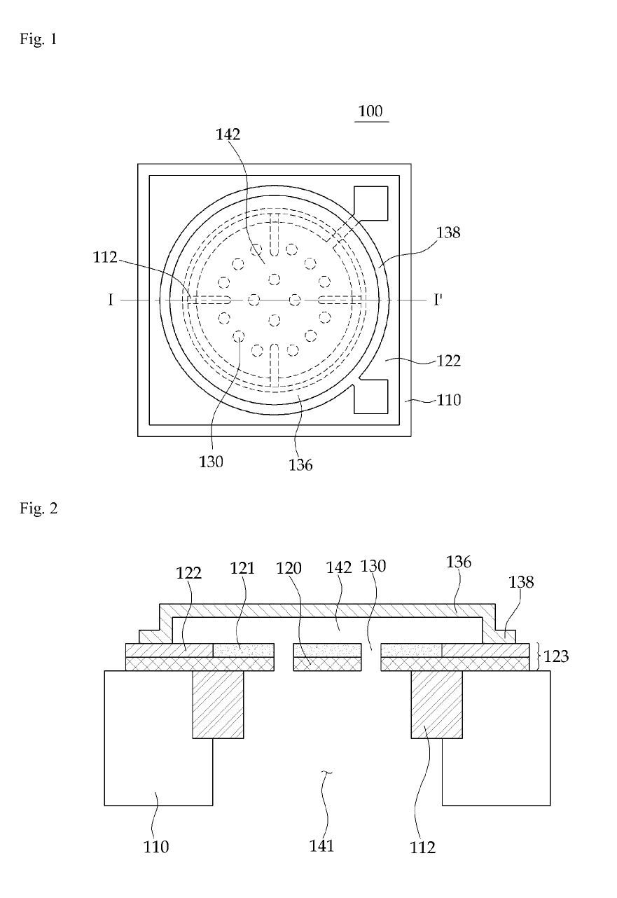

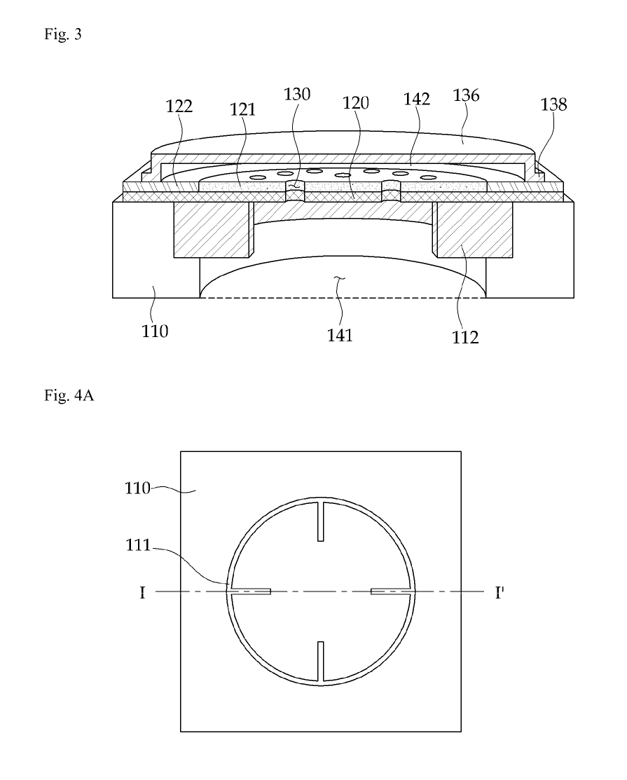

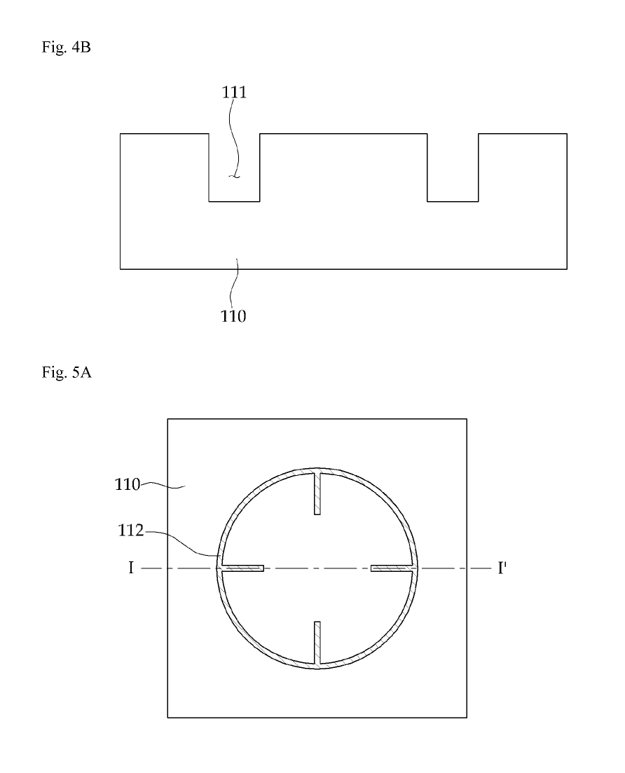

FIG. 1 is a top view of a micro electro mechanical system (MEMS) acoustic sensor according to an exemplary embodiment of the present disclosure, and is a top view of an acoustic sensor according to an exemplary embodiment of the present disclosure, FIG. 2 is a cross-sectional view taken along line I-I′ of FIG. 1, and FIG. 3 is a perspective view taken along line I-I′ of FIG. 1.

Referring to FIGS. 1 to 3, an acoustic sensor 100 according to an exemplary embodiment of the present disclosure may include a substrate 110 on which a fixing pin 112 is formed and in which inside of the fixing pin 112 is hollow, a fixed electrode 123 fixed on the substrate 110 using the fixing pin 112, a diaphragm 136 formed to be separate from above the fixed electrode 123 by a predetermined interval and configured to vibrate in reaction to external sound pressure, a diaphragm supporter 138 configured to support the diaphragm 136 on the side of the diaphragm 136, and an acoustic chamber 141 formed in a space covered by the substrate 110 and the fixed electrode 123. The fixed electrode 123 includes a substrate insulating film 120, a lower electrode 121, and a lower electrode insulating film 122.

More specifically, the substrate 110 may be a silicone (Si) substrate or a compound semiconductor substrate. For example, the group 3-5 compound semiconductor substrate may be formed using gallium arsenide (GaAs) or InP. The substrate 110 may be a rigid substrate or a flexible substrate.

The substrate 110 includes the fixing pin 112. The fixing pin 112 functions to fix the fixed electrode 123 to the substrate 110. When the fixed electrode 123 is fixed to the substrate 110 using the fixing pin 112, only the diaphragm 136 linearly reacts to external sound pressure and thus, may become to have an excellent frequency characteristic.

The fixing pin 112 may have a width of one to several μm and a depth of ten to hundreds of μm, may be in a closed-loop form, and may be formed as an oxide film.

The fixed electrode 123 may include the substrate insulating film 120, the lower electrode 121, and the lower electrode insulating film 122 that are sequentially formed on the substrate 110. The substrate insulating film 120 and the lower electrode insulating film 122 may be formed as an oxide film or an organic film. Depending on necessity, the substrate insulating film 120 may be omitted.

A sound pressure input hole 130 is formed in the fixed electrode 123. The sound pressure input hole 130 functions to receive the sound pressure through the acoustic chamber 141, and is used as an etching path for removing a sacrificial layer. Removing the sacrificial layer will be described in detail below.

The diaphragm 136 is positioned to face the fixed electrode 123 based on a diaphragm gap 142. The diaphragm 136 is used as a relative electrode of the fixed electrode 123. The fixed electrode 123 and the diaphragm 136 constitute a pair of electrodes.

The diaphragm 136 may be provided in a single layer structure of a conductive layer, or in a multi-layer structure of an insulating layer and the conductive layer. The conductive layer may be formed using, for example, a metal. The diaphragm 136 may be provided in a circular shape with a thickness of several μm.

The diaphragm supporter 138 may be provided on the lower electrode insulating film 122 on the side of the diaphragm 136 so that the diaphragm 136 may react when vibration occurs due to the sound pressure. The diaphragm supporter 138 may be provided in an integrated type that is extended from one edge of the diaphragm 136. The diaphragm supporter 138 may be formed using the same material as the diaphragm 136.

The acoustic chamber 141 is formed within the substrate 110 below the fixed electrode 123. The acoustic chamber 141 is formed by etching the bottom surface of the substrate 110. After forming the acoustic chamber 141, the diaphragm gap 142 is formed through the sound pressure input hole 130.

As described above, the MEMS acoustic sensor 100 of the present disclosure may tightly fix the fixed electrode 123 to the substrate 110 using the fixing pin 112 and thus, may improve a frequency response characteristic by removing an undesired vertical motion of the fixed electrode 123 when the sound pressure is received.

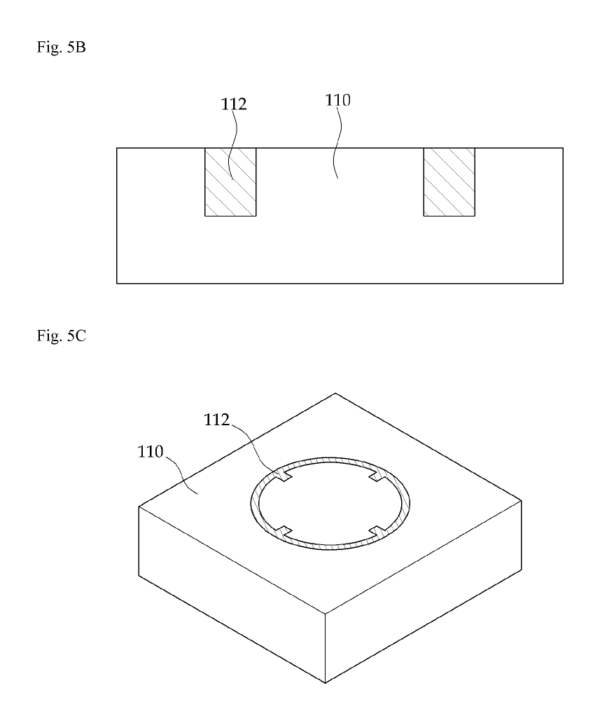

Hereinafter, a method of fabricating a MEMS acoustic sensor according to an exemplary embodiment of the present disclosure will be schematically described with reference to FIGS. 4A to 10C.

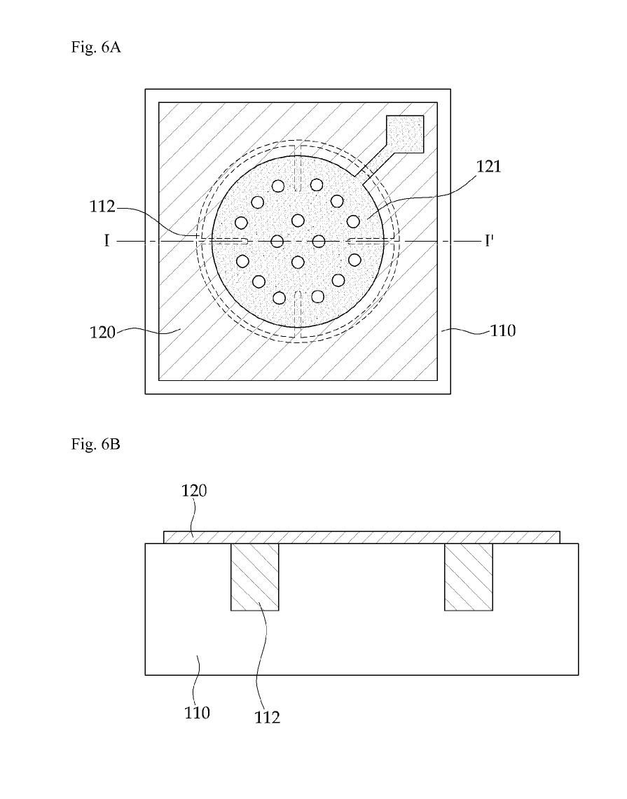

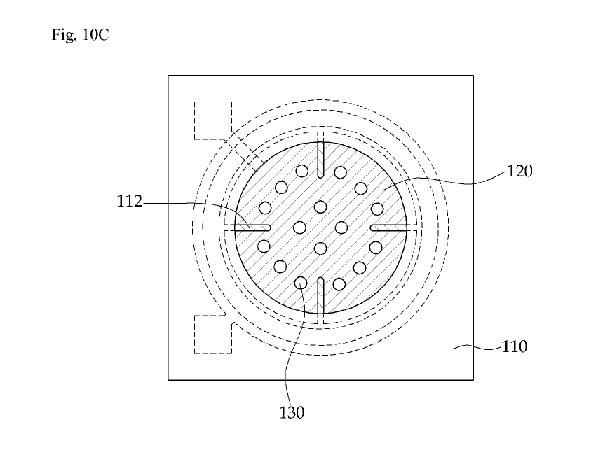

FIGS. 4A, 5A, 6A, 7A, 8A, 9A, and 10A are top views and FIGS. 4B, 5B, 6B, 7B, 8B, 9B, and 10B are cross-sectional views taken along lines I-I′ of FIGS. 4A, 5A, 6A, 7A, 8A, 9A, and 10A to describe a method of fabricating an acoustic sensor according to an exemplary embodiment of the present disclosure, and FIG. 5C is a perspective view of FIG. 5A, and FIG. 10C is a top view observed from the bottom surface of the substrate 110 of FIG. 10A.

Initially, referring to FIGS. 4A and 4B, a fixing pin groove 111 is formed on the substrate 110.

Here, the substrate 110 may be a Si substrate or a compound semiconductor substrate. For example, the group 3-5 compound semiconductor substrate may be formed using GaAs or InP. The substrate 110 may be a rigid substrate or a flexible substrate.

The fixing pin groove 111 may be formed using a dry etching method. The fixing pin groove 111 may be in a closed-loop form of a circular structure. Here, the fixing pin groove 111 may be formed to have a width of one to several μm and a depth of ten to hundreds of μm.

As illustrated in FIGS. 5A to 5C, when the fixing pin groove 111 is formed, the fixing pin 112 is formed on the fixing pin groove 111. The fixing pin 112 may be formed as an oxide film. The fixing pin 112 is formed by forming an insulating film (not shown) on the substrate 110 including the fixing pin groove 111 and then flattening the formed insulating film. Here, flattening may be performed using blanket etching, etchback, a chemical mechanical polishing (CMP) process, and the like.

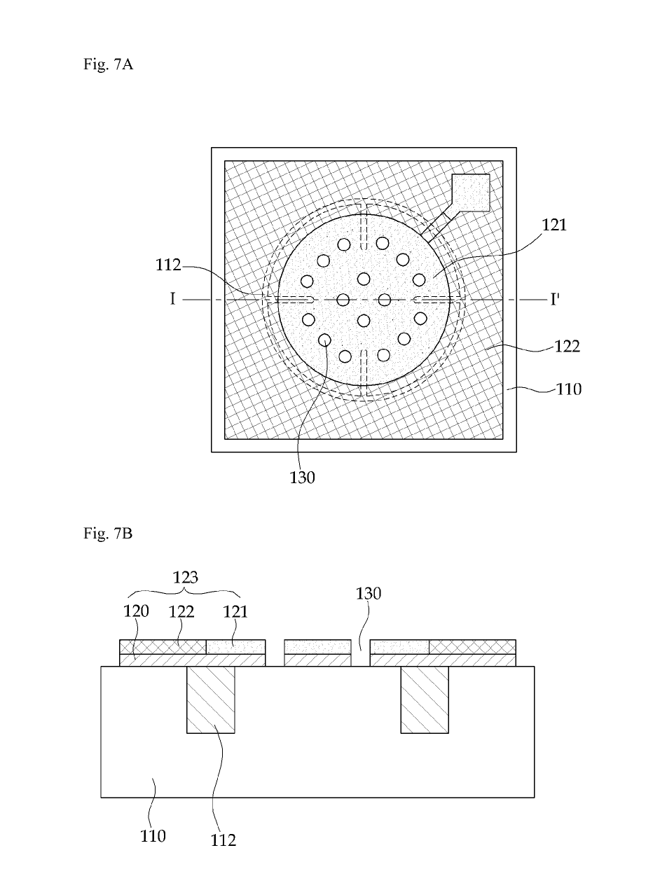

Next, as illustrated in FIGS. 6A and 6B, the substrate insulating film 120 is formed on the fixing pin 112 and the exposed substrate 110.

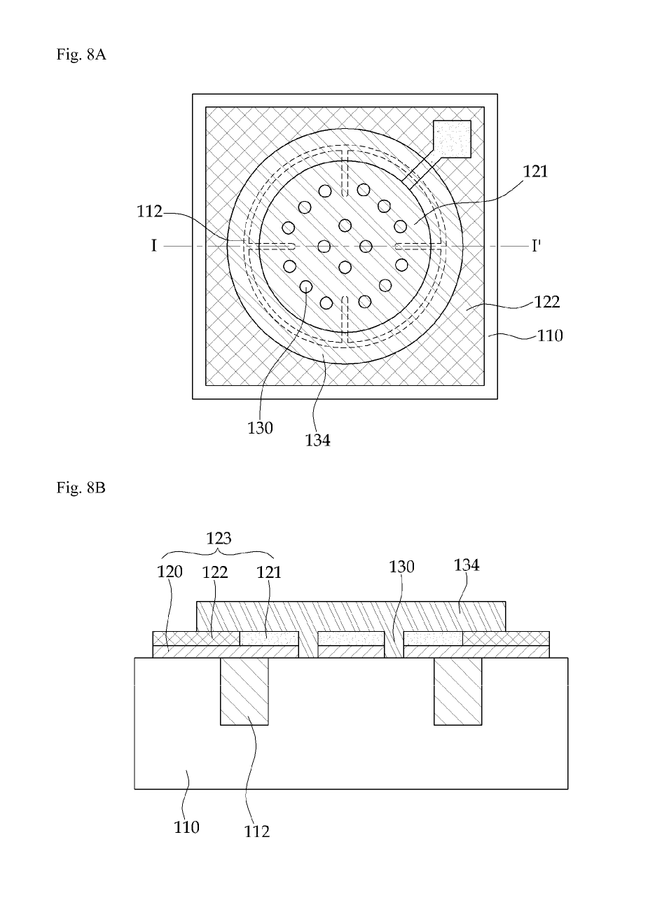

Referring to FIGS. 7A and 7B, the lower electrode 121 and the lower electrode insulating film 122 are sequentially formed on the substrate insulating film 120. The substrate insulating film 120 is to insulate the lower electrode 121 from the substrate 110 and thus, may be omitted depending on cases.

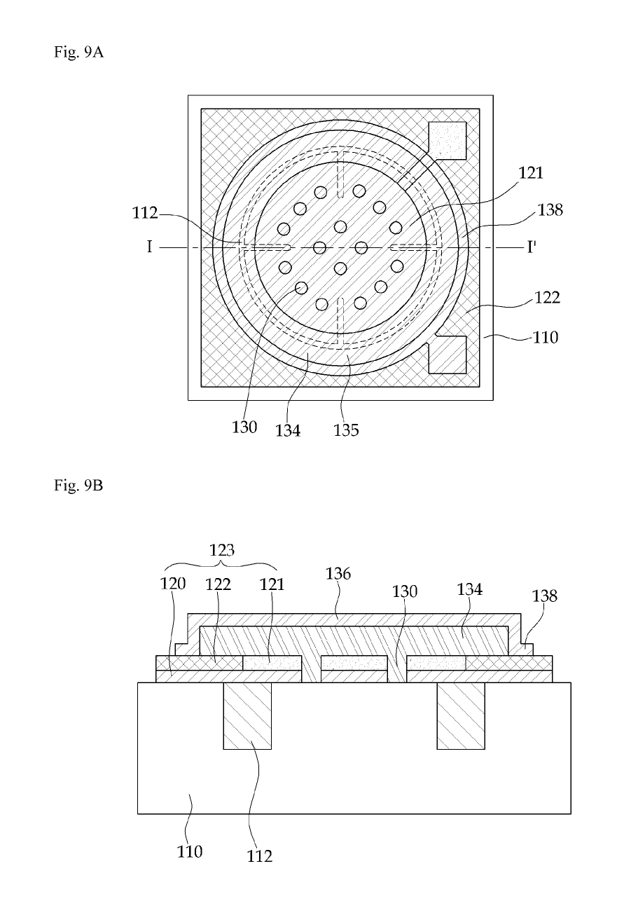

The lower electrode insulating film 122 is to insulate the lower electrode 121 from the diaphragm 136 (see FIG. 8B) to be subsequently formed. The substrate insulating film 120 and the lower electrode insulating film 122 may be formed as an oxide film or an organic film. Here, the substrate insulating film 120, the lower electrode 121, and the lower electrode insulating film 122 constitute the fixed electrode 123 of the acoustic sensor 100 (see FIG. 7B).

Holes 130 are formed within the fixed electrode 123 so that the acoustic chamber 141 (see FIG. 10B) may be formed during a subsequent process. The holes 130 may be defined as sound pressure input holes. The sound pressure input holes 130 are formed to be positioned on a further inner portion than the fixing pin 112.

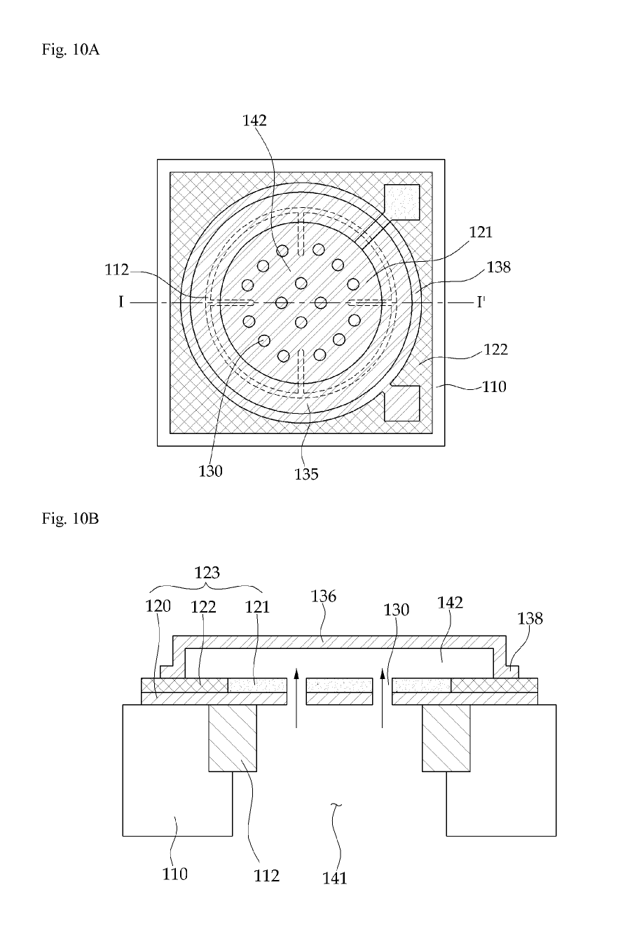

Referring to FIGS. 8A and 8B, a sacrificial layer 134 is formed on the lower electrode insulating film 122. The sacrificial layer 134 is to enable the diaphragm 136 (see FIG. 9) formed during a subsequent process to be afloat in the air. The sacrificial layer 134 may be formed as, for example, an oxide film or an organic film. The sacrificial layer 134 may be formed using a material having etching selectivity different from the substrate insulating film 120 and the lower electrode insulating film 122. The sacrificial layer 134 may be formed to have a thickness of several μm.

Referring to FIGS. 9A and 9B, the diaphragm 136 is formed on the sacrificial layer 134. The diaphragm 136 has a thickness of several μm. The diaphragm 136 may be formed in a single structure of a conductive layer or in a multi-layer structure of an insulating layer and the conductive layer. Here, the conductive layer is used as a relative electrode and is formed using a metal. The insulating layer may be an oxide film or an organic film having etching selectivity different form the sacrificial layer 134.

When forming the diaphragm 136, it is possible to form the diaphragm supporter 138 on the lower electrode insulating film 122 that is formed on each of both sides of the diaphragm 136. The diaphragm 136 and the diaphragm supporter 138 are formed by forming a conductive layer film or a multi-layer film of the insulating layer and the conductive layer on the sacrificial layer 134 and the exposed lower electrode insulating film 122 and then patterning the formed conductive layer film or multi-layer film using a photolithography process.

Referring to FIGS. 10A to 10C, the acoustic chamber 141 is formed by etching a portion of the substrate 110 of the acoustic sensor 100 so that the substrate insulating film 120 and the sound pressure input hole 130 are exposed. Next, the diaphragm gap 142 is formed.

The acoustic chamber 141 may be formed by etching the substrate 110 using a dry etching method. When the substrate 110 is a Si substrate, an etching process may be performed using a dry etching process. The dry etching process may be performed using, for example, XeF2 gas that enables anisotropic etching. That is, the dry etching process may be performed by injecting appropriate etching gas into a forming material of the substrate 110.

The diaphragm gap 142 is formed by etching the sacrificial layer 134 through the sound chamber 141 formed in a lower area of the acoustic sensor 100 and the sound pressure input hole 130 formed in the fixed electrode 123. Specifically, the sacrificial layer 134 (of FIG. 9B) may be etched by injecting etching gas through the sound pressure input hole 130 and by enabling the etching gas to flow into above the fixed electrode 123. The sacrificial layer 134 (of FIG. 9B) may be removed through etching using a dry etching method. When the sacrificial layer 134 is an organic film, the etching process may be performed using, for example, O₂ gas. That is, the etching process may be performed by injecting, into above the sacrificial layer 134, etching gas appropriate for a forming material of the sacrificial layer 134. Accordingly, as the etching gas flows in the sacrificial layer 134 through the sound pressure input hole 130, the sacrificial layer 134 between the lower electrode insulating layer 122 and the diaphragm 136 may be removed. Here, an arrow indicator indicates an etching progress direction of the etching gas. Accordingly, an empty space between the lower electrode insulating films 122 provided on the diaphragm 136 is formed as the diaphragm gap 142 that is used as a vibrating space of the diaphragm 136. As a result, the fixed electrode 123 and the diaphragm 136 are separate from each other by a predetermined distance to thereby face each other. As described above, the sacrificial layer 134 (of FIG. 9B) may be etched through the sound pressure input holes 130 and thereby be removed.

Accordingly, the acoustic sensor 100 including the substrate 110 having the fixing pin 112, the fixed electrode 123, the diaphragm 136 facing the fixed electrode 123 and separate from the fixed electrode 123 by a predetermined interval, and the acoustic chamber 141.

According to an exemplary embodiment of the present disclosure, the acoustic sensor 100 may tightly fix the lower electrode 121 within the substrate 110 by inserting the fixing pin 112 into and below the fixed electrode 123 and thus, may improve a frequency response characteristic by removing an undesired vertical motion of the fixed electrode 123 when sound pressure is received.

The acoustic sensor 100 may improve a yield of a process by inhibiting thermal deformation of the fixed electrode 123 that may occur during the process through insertion of the fixing pin 112.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of fabricating a micro electro mechanical system (MEMS) acoustic sensor, the method comprising:
forming a fixing groove by etching a portion of a substrate;
forming a fixing pin by forming an insulating film on the substrate on which the fixing groove is formed, and by flattening the formed insulating film;
forming a fixed electrode on the substrate on which the fixing pin is formed;
forming a sacrificial layer on the fixed electrode;
forming a diaphragm to face the fixed electrode based on the sacrificial layer, and a diaphragm supporter to support the diaphragm on the side of the diaphragm;
forming an acoustic chamber by etching a portion of the substrate; and
etching and thereby removing the sacrificial layer.

2. The method of claim 1, wherein the forming of the fixed electrode comprises:
sequentially forming, on the substrate, a substrate insulating film, a lower electrode, and a lower electrode insulating film; and
forming a sound pressure input hole that penetrates from the lower electrode insulating film to the substrate insulating film.

3. The method of claim 2, wherein the removing of the sacrificial layer etches and thereby removes the sacrificial layer by injecting etching gas through the sound pressure input hole from the acoustic chamber.

4. The method of claim 3, wherein the sacrificial layer is formed using a material having etching selectivity different from the lower electrode insulating film and the substrate insulating film.

5. The method of claim 1, wherein the forming of the fixing pin flattens the insulating film so that the substrate surface on which the fixing groove is not formed is exposed.

6. A MEMS acoustic sensor, comprising:
a substrate on which a fixing pin is formed and in which inside of the fixing pin is hollow;
a fixed electrode fixed on the substrate using the fixing pin; and
a diaphragm formed to be separate from above the fixed electrode by a predetermined interval, and configured to vibrate in reaction to external sound pressure,
wherein an acoustic chamber is formed in a space covered by the substrate and the fixed electrode.

7. The MEMS acoustic sensor of claim 6, wherein the fixed electrode includes a lower electrode, a lower electrode insulating film, and a substrate insulating film.

8. The MEMS acoustic sensor of claim 6, wherein at least one sound pressure input hole for receiving sound pressure through the acoustic chamber is formed in the fixed electrode.

9. The MEMS acoustic sensor of claim 7, further comprising:
a diaphragm supporter formed on the lower electrode insulating film to connect the diaphragm to the substrate.

10. The MEMS acoustic sensor of claim 9, wherein the diaphragm supporter is integrally formed with the diaphragm.
